(19) United States
(12) Patent Application Publication
(10) Pub. No.: US 2015/0147535 A1
(43) Pub. Date: May 28, 2015

(54) LAMINATE

(71) Applicant: Lee-Sheng Yen, Yaoyuan City (TW)

(72) Inventor: Lee-Sheng Yen, Yaoyuan City (TW)

(21) Appl. No.: 14/090,329

(22) Filed: Nov. 26, 2013

(51) Int. Cl. B32B 15/04; H05K 1/03; H05K 3/46; B32B 33/00; H05K 3/00

(52) U.S. Cl. CPC B32B 15/04; B32B 33/00; H05K 3/0067; H05K 3/4611; H05K 1/03; H05K 2201/032; B32B 2307/748; B32B 2311/12
USPC 428/189; 428/457

(57) ABSTRACT

A laminate is disclosed, which includes: a core layer having an adhesive property; an isolation layer directly adhered to the core layer; and a metal layer attached onto the isolation layer such that the isolation layer is sandwiched between the metal layer and the core layer. Therein, the metal layer is directly adhered to the core layer through an outer peripheral portion thereof and not attached to the isolation layer. As such, during fabrication of a packaging substrate, the metal layer and the isolation layer can be automatically separated from each other by removing the bonding portions of the metal layer and the core layer.

REFERENCE TO RELATED APPLICATION

This application claims foreign priority under 35 U.S.C. §119(a) to Patent Application No. 102135965, filed on Oct. 4, 2013, in the Intellectual Property Office of Ministry of Economic Affairs, Republic of China (Taiwan, R.O.C.), the entire content of which Patent Application is incorporated herein by reference.

### BACKGROUND OF THE INVENTION

1. Field of the Invention

The present invention relates to laminates, and more particularly, to a laminate used for a semiconductor process.

2. Description of Related Art

Along with the rapid development of electronic industries, electronic products are gradually developed toward high functionality and high performance. Therefore, various types of semiconductor package structures have been developed. Generally, a chip is disposed on and electrically connected to a packaging substrate first and then an encapsulant is formed on the packaging substrate to encapsulate the chip. Finally, the packaging substrate with the chip is mounted on a circuit board so as to form a semiconductor package structure. The packaging substrate has a plurality of conductive pads for electrically connecting the packaging substrate to the chip or the circuit board.

FIGS. 1A to 1D are schematic cross-sectional views showing a method for fabricating a packaging substrate 1′ according to the prior art.

Referring to FIG. 1A, a laminate 1 such as a copper clad laminate (CCL) is provided. The laminate 1 has a core layer 10 having opposite surfaces 10a, 10b, and a copper layer 12 formed on each of the surfaces 10a, 10b of the core layer 10.

Referring to FIG. 1B, a circuit layer 13 and an RDL (redistribution layer) structure 14 are sequentially formed on the copper layer 12 on each of the surfaces 10a, 10b of the core layer 10 by electroplating. The circuit layer 13 has a plurality of conductive pads 130 and the RDL structure 14 has a plurality of conductive pads 140.

Referring to FIG. 1C, the copper layer 12 and the core layer 10 are separated from each other so as to obtain two packaging substrates 1′.

Referring to FIG. 1D, the copper layer 12 is removed by etching to expose the conductive pads 130 of the circuit layer 13. As such, a plurality of conductive bumps can be formed on the conductive pads 130, 140 for electrically connecting a semiconductor chip (not shown) or a circuit board (not shown).

However, since the copper layer 12 is directly adhered to the surfaces 10a, 10b of the core layer 10, when the copper layer 12 is separated from the core layer 10 by an external mechanical force, the circuit layer 13 can be easily damaged under the effect of the adhesion force or stresses. For example, a crack may extend from the copper layer 12 to the circuit layer 13.

Further, if the bonding between the core layer 10 and the copper layer 12 is removed by a mechanical method or a chemical solution, the circuit layer 13 is easily damaged.

Therefore, there is a need to provide a laminate so as to overcome the above-described drawbacks.

### SUMMARY OF THE INVENTION

In view of the above-described drawbacks, the present invention provides a laminate, which comprises: a core layer having an adhesive property; an isolation layer directly adhered to the core layer; and a metal layer attached onto the isolation layer such that the isolation layer is sandwiched between the metal layer and the core layer, wherein the metal layer is directly adhered to the core layer and not attached to the isolation layer.

According to the present invention, the metal layer is directly adhered to the core layer through an outer peripheral portion thereof and not attached to the isolation layer. As such, during fabrication of a packaging substrate, the metal layer and the isolation layer can be automatically separated from each other by removing the outer peripheral portion of the metal layer and the portion of the core layer bonded with the metal layer, thereby eliminating the need to use an external mechanical force or a chemical solution to separate the metal layer and the isolation layer and hence ensuring the integrity of circuit layers of the packaging substrate.

### BRIEF DESCRIPTION OF DRAWINGS

FIGS. 1A to 1D are schematic cross-sectional views showing a method for fabricating a packaging substrate according to the prior art;

FIGS. 2A to 2B are schematic cross-sectional views showing a method for fabricating a laminate according to the present invention, wherein FIG. 2A′ is a schematic upper view of the laminate of FIG. 2A;

FIG. 3 is a schematic cross-sectional view of a laminate according to another embodiment of the present invention; and

FIG. 4 is a schematic cross-sectional view showing a method for fabricating a packaging substrate using the laminate of the present invention.

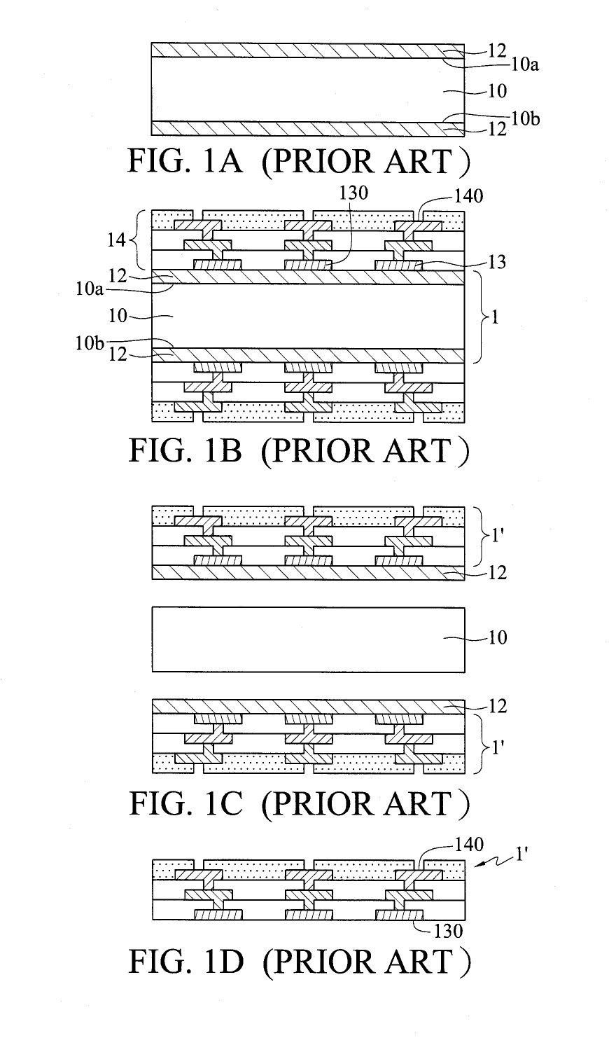

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “upper”, “on”, “a” etc. are merely for illustrative purposes and should not be construed to limit the scope of the present invention.

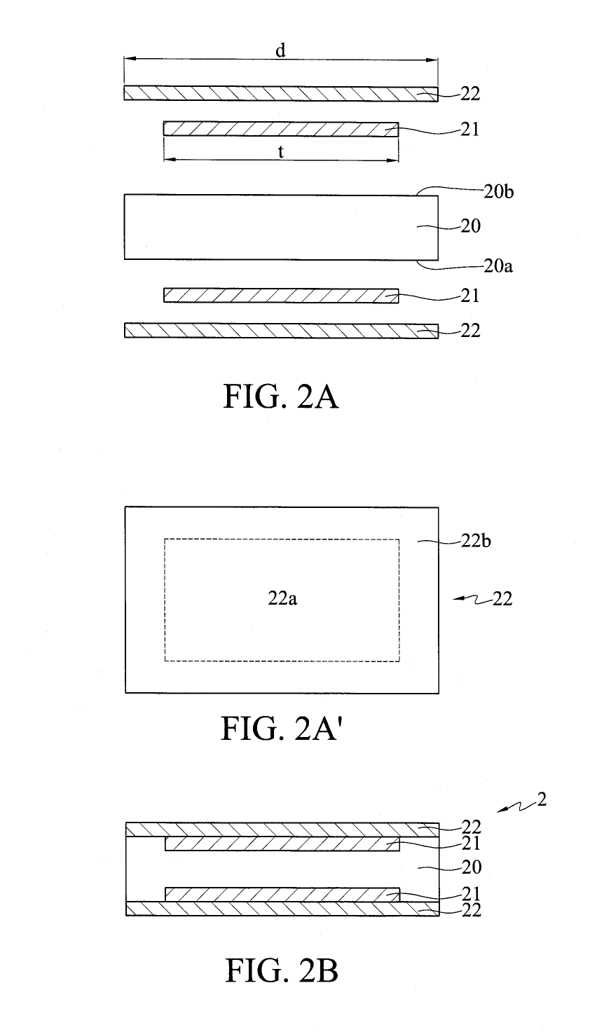

FIGS. 2A to 2B are schematic cross-sectional views showing a method for fabricating a laminate 2 according to the present invention. In the present embodiment, the laminate 2 is a copper clad laminate.

Referring to FIG. 2A, a core layer 20 having an adhesive property is provided. The core layer 20 has two opposite surfaces 20a, 20b, and an isolation layer 21 and a metal layer 22 are sequentially stacked on each of the surfaces 20a, 20b of the core layer 20.

The isolation layer 21 is made of metal. For example, the isolation layer 21 can be fully or partially made of copper or aluminum to serve as a metal release layer. The isolation layer 21 does not have an adhesive property. In other embodiments, the isolation layer 21 can be made of an insulating material that does not have an adhesive property after being cured. For example, the isolation layer 21 can be made of PE (polyethylene), PI (polyimide) and PET (polyethylene terephthalate).

Further, the metal layer 22 is a copper layer and has a width d substantially equal to the width of the core layer 20 and greater than the width t of the isolation layer 21. Referring to FIG. 2A′, the metal layer 22 is defined with an effective area 22a and a non-effective area 22b around the effective area 22a. The effective area 22a will be used for fabricating a packaging substrate, and the non-effective area 22b will be discarded.

Referring to FIG. 2B, the core layer 20, the isolation layer 21 and the metal layer 22 are laminated together such that the isolation layer 21 is sandwiched between the core layer 20 and the metal layer 22. Therein, the isolation layer 21 is directly adhered to the core layer 20, and the metal layer 22 is directly adhered to the core layer 20 and in contact with, but not attached to, the isolation layer 21.

In the present embodiment, the effective area 22a is in contact with the isolation layer 21, and the non-effective area 22b is directly adhered to the core layer 20 and not in contact with the isolation layer 21.

Since the core layer 20 has an adhesive property, the isolation layer 21 and the non-effective area 22b of the metal layer 22 can be directly adhered to the core layer 20 without the need of an adhesive material.

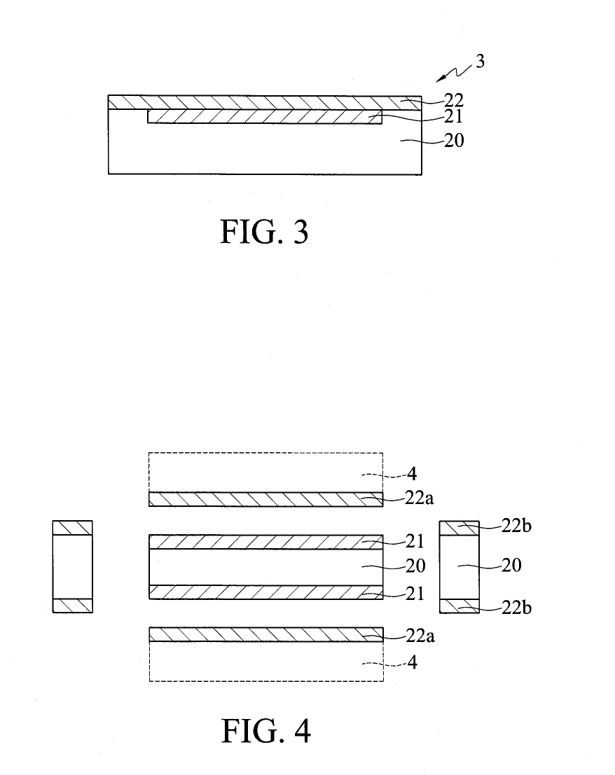

FIG. 3 is a schematic cross-sectional view of a laminate 3 according to another embodiment of the present invention. In the present embodiment, the laminate 3 has a core layer 20, and an isolation layer 21 and a metal layer 22 formed on an upper surface of the core layer 20.

Subsequently, referring to FIG. 4, a packaging substrate 4 (as shown in dashed lines) similar to the packaging substrate 1′ can be fabricated based on the metal layer 22 of the laminate 2, 3. Then, the non-effective area 22b of the metal layer 22 is removed by cutting so as to automatically separate the effective area 22a of the metal layer 22 and the isolation layer 21. As such, two packaging substrates 4 are obtained.

According to the present invention, the effective area 22a of the metal layer 22 is in contact with but not attached to the isolation layer 21 and the non-effective area 22b of the metal layer 22 is directly adhered to the core layer 20. As such, during fabrication of a packaging substrate, the effective area 22a and the isolation layer 21 can be automatically separated from each other by removing the non-effective area 22b and the portion of the core layer 20 bonded with the non-effective area 22b, thereby eliminating the need to use an external mechanical force or a chemical solution to separate the metal layer 22 and the isolation layer 21 and hence ensuring the integrity of circuit layers of the packaging substrate.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A laminate, comprising:
a core layer having an adhesive property;
an isolation layer directly adhered to the core layer; and
a metal layer attached onto the isolation layer such that the isolation layer is sandwiched between the metal layer and the core layer, wherein the metal layer is directly adhered to the core layer and not attached to the isolation layer.

2. The laminate of claim 1, wherein the core layer has two opposite surfaces for the isolation layer and the metal layer to be attached thereonto.

3. The laminate of claim 1, wherein the isolation layer is free from having an adhesive property.

4. The laminate of claim 1, wherein the isolation layer comprises metal.

5. The laminate of claim 1, wherein the isolation layer is a metal release layer.

6. The laminate of claim 1, wherein the metal layer is defined with an effective area and a non-effective area around the effective area, the effective area being in contact with the isolation layer and the non-effective area being directly adhered to the core layer and not in contact with the isolation layer.

7. The laminate of claim 1, wherein the metal layer is greater in width than the isolation layer.

8. The laminate of claim 1, wherein the metal layer is a copper layer.
